(19) United States
(12) Patent Application Publication
(10) Pub. No.: US 2023/0387373 A1
(43) Pub. Date: Nov. 30, 2023

(54) LIGHT EMITTING MODULE AND METHOD OF MANUFACTURING SAME

(71) Applicant: NICHIA CORPORATION, Anan-shi (JP)

(72) Inventors: Hiroki TOMINAGA, Tokushima-shi (JP); Kosuke SATO, Anan-shi (JP)

(73) Assignee: NICHIA CORPORATION, Anan-shi (JP)

(21) Appl. No.: 18/320,668

(22) Filed: May 19, 2023

(30) Foreign Application Priority Data
May 31, 2022 (JP) 2022-088670

(51) Int. Cl. H01L 33/62; H01L 25/075; H01L 23/00

(52) U.S. Cl. CPC H01L 33/62; H01L 25/0753; H01L 24/32; H01L 24/29; H01L 24/83; H01L 24/30; H01L 2224/29023; H01L 2224/29013; H01L 2224/30131; H01L 2224/32227; H01L 2224/83931; H01L 2933/0066; H01L 2924/12041

(57) ABSTRACT

A method of manufacturing a light emitting module includes: providing an intermediate structure that includes a wiring board having an upper surface and including a metal layer, a first conducting member on the metal layer, and a second conducting member on the metal layer; disposing, on the intermediate structure, a resist layer having openings; providing a light emitting element including a first electrode and a second electrode, and disposing the light emitting element on the resist layer such that the first electrode and the second electrode respectively face the first conducting member and the second conducting member while a portion of an outer periphery of the lower surface of the light emitting element is exposed from the resist layer in the openings; forming a first bonding member on the first conducting member and forming a second bonding member on the second conducting member; and removing the resist layer.

### CROSS REFERENCE TO RELATED APPLICATION

This application claims priority to Japanese Patent Applications No. 2022-088670, filed on May 31, 2022, the entire contents of which are hereby incorporated by reference.

### BACKGROUND

The present disclosure relates to a light emitting module and a method of manufacturing the same.

A light emitting module having a large number of semiconductor elements mounted on a single wiring board has been disclosed. See, for example, Japanese Patent Publication No. 2021-103774. For such a light emitting module, the production efficiency needs to be further improved.

### SUMMARY

One object of certain embodiments of the present invention is to provide a light emitting module that allows for improved production efficiency and a method of manufacturing the same.

A method of manufacturing a light emitting module according to an embodiment of the present invention includes: providing an intermediate structure that includes a wiring board having an upper surface and including a metal layer disposed on the upper surface, a first conducting member disposed on the metal layer to be in contact with the metal layer, and a second conducting member disposed on the metal layer to be in contact with the metal layer and apart from the first conducting member; disposing, on the intermediate structure, a resist layer having a first opening and a second opening such that the first conducting member is exposed in the first opening and the second conducting member is exposed in the second opening; providing a light emitting element having a lower surface, the light emitting element including a first electrode and a second electrode that are spaced apart from each other on the lower surface, and disposing the light emitting element on the resist layer such that the first electrode and the second electrode respectively face the first conducting member and the second conducting member while a portion of the outer periphery of the lower surface is exposed from the resist layer in the first opening and the second opening; forming a first bonding member on the first conducting member to be in contact with the first conducting member and the first electrode and forming a second bonding member on the second conducting member to be apart from the first bonding member and in contact with the second conducting member and the second electrode; and removing the resist layer.

A light emitting module according to an embodiment of the present invention includes: a wiring board having an upper surface, the wiring board including a first metal layer disposed on the upper surface, and a second metal layer disposed on the upper surface; a first conducting member disposed on the first metal layer in contact with the first metal layer; a second conducting member disposed on the second metal layer in contact with the second metal layer; a first bonding member disposed on the first conducting member in contact with the first conducting member; a second bonding member disposed on the second conducting member in contact with the second conducting member; and a light emitting element having a lower surface, the light emitting element including a first electrode disposed on the lower surface and in contact with the first bonding member, and a second electrode disposed on the lower surface and in contact with the second bonding member, the lower surface opposing the upper surface of the wiring board. In a plan view, a portion at the ends of the first conducting member is exposed from the first bonding member, and a portion at the ends of the second conducting member is exposed from the second bonding member.

According to certain embodiments of the present invention, a light emitting module which allows for improved production efficiency and a method of manufacturing the same can be provided.

### BRIEF DESCRIPTION OF THE DRAWINGS

FIG. 1 is a plan view showing a method of manufacturing a light emitting module according to a first embodiment.

FIG. 2A is an end view taken along line IIA-IIA in FIG. 1.

FIG. 2B is an end view taken along line IIB-IIB in FIG. 1.

FIG. 2C is an end view taken along line IIC-IIC in FIG. 1.

FIG. 2D is an end view taken along line IID-IID in FIG. 1.

FIG. 3 is a plan view showing the method of manufacturing a light emitting module according to the first embodiment.

FIG. 4A is an end view taken along line IVA-IVA in FIG. 3.

FIG. 4B is an end view taken along line IVB-IVB in FIG. 3.

FIG. 4C is an end view taken along line IVC-IVC in FIG. 3.

FIG. 4D is an end view taken along line IVD-IVD in FIG. 3.

FIG. 5 is a plan view showing the method of manufacturing a light emitting module according to the first embodiment.

FIG. 6A is an end view taken along line VIA-VIA in FIG. 5.

FIG. 6B is an end view taken along line VIB-VIB in FIG. 5.

FIG. 6C is an end view taken along line VIC-VIC in FIG. 5.

FIG. 6D is an end view taken along line VID-VID in FIG. 5.

FIG. 7 is a plan view showing the method of manufacturing a light emitting module according to the first embodiment.

FIG. 8A is an end view taken along line VIIIA-VIIIA in FIG. 7.

FIG. 8B is an end view taken along line VIIIB-VIIIB in FIG. 7.

FIG. 8C is an end view taken along line VIIIC-VIIIC in FIG. 7.

FIG. 8D is an end view taken along line VIIID-VIIID in FIG. 7.

FIG. 9 is a plan view showing the method of manufacturing a light emitting module according to the first embodiment.

FIG. 10A is an end view taken along line XA-XA in FIG. 9.

FIG. 10B is an end view taken along line XB-XB in FIG. 9.

FIG. 10C is an end view taken along line XC-XC in FIG. 9.

FIG. 10D is an end view taken along line XD-XD in FIG. 9.

FIG. 11 is a plan view showing the method of manufacturing a light emitting module according to the first embodiment.

FIG. 12A is an end view taken along line XIIA-XIIA in FIG. 11.

FIG. 12B is an end view taken along line XIIB-XIIB in FIG. 11.

FIG. 12C is an end view taken along line XIIC-XIIC in FIG. 11.

FIG. 12D is an end view taken along line XIID-XIID in FIG. 11.

FIG. 13 is a plan view showing the method of manufacturing a light emitting module according to the first embodiment.

FIG. 14A is an end view taken along line XIVA-XIVA in FIG. 13.

FIG. 14B is an end view taken along line XIVB-XIVB in FIG. 13.

FIG. 14C is an end view taken along line XIVC-XIVC in FIG. 13.

FIG. 14D is an end view taken along line XIVD-XIVD in FIG. 13.

FIG. 15 is a plan view showing the method of manufacturing a light emitting module according to the first embodiment.

FIG. 16A is an end view taken along line XVIA-XVIA in FIG. 15.

FIG. 16B is an end view taken along line XVIB-XVIB in FIG. 15.

FIG. 16C is an end view taken along line XVIC-XVIC in FIG. 15.

FIG. 16D is an end view taken along line XVID-XVID in FIG. 15.

FIG. 17A is an end view showing a method of manufacturing a light emitting module according to a second embodiment.

FIG. 17B is an end view showing the method of manufacturing a light emitting module according to a second embodiment.

FIG. 17C is an end view showing the method of manufacturing a light emitting module according to a second embodiment.

### DETAILED DESCRIPTION

### First Embodiment

Certain embodiments of the present invention will be explained below with reference to the accompanying drawings. Each drawing is schematic, and includes emphasis or is simplified as appropriate. The dimensional ratio of constituent elements might not necessarily match among the drawings.

A method of manufacturing a light emitting module according to a first embodiment will be explained below.

A general description will be provided first.

A method of manufacturing a light emitting module 1 according to this embodiment includes: a step of providing an intermediate structure 20 that includes a wiring board 10 having an upper surface 16 and a metal layer 13 disposed on the upper surface 16, a first conducting member 21 disposed on the metal layer 13 in contact with the metal layer 13, and a second conducting member 22 disposed on the metal layer 13 in contact with the metal layer 13 apart from the first conducting member 13; a step of disposing on the intermediate structure 20 a resist layer 30 having a first opening 31 and a second opening 32, exposing the first conducting member 21 at the first opening 31 and exposing the second conducting member 22 at the second opening 32; a step of providing a light emitting element 40 having a lower surface 41, a first electrode 46 and a second electrode 47 disposed apart from one another on the lower surface 41, and disposing the light emitting element 40 on the resist layer 30 so as to oppose the first electrode 46 and the second electrode 47 to the first conducting member 21 and the second conducting member 22, respectively, while partly exposing the outer periphery 41a of the lower surface 41 from the resist layer 30 in the first opening 31 and the second opening 32; a step of forming on the first conducting member 21 a first bonding member 51 to be in contact with the first conducting member 21 and the first electrode 46 and forming on the second conducting member 22 a second bonding member 52 to be apart from the first bonding member 51 and in contact with the second conducting member 22 and the second electrode 47; and a step of removing the resist layer 30. The method will be explained in detail below.

### Step of Providing Intermediate Structure

An intermediate structure 20 is provided first.

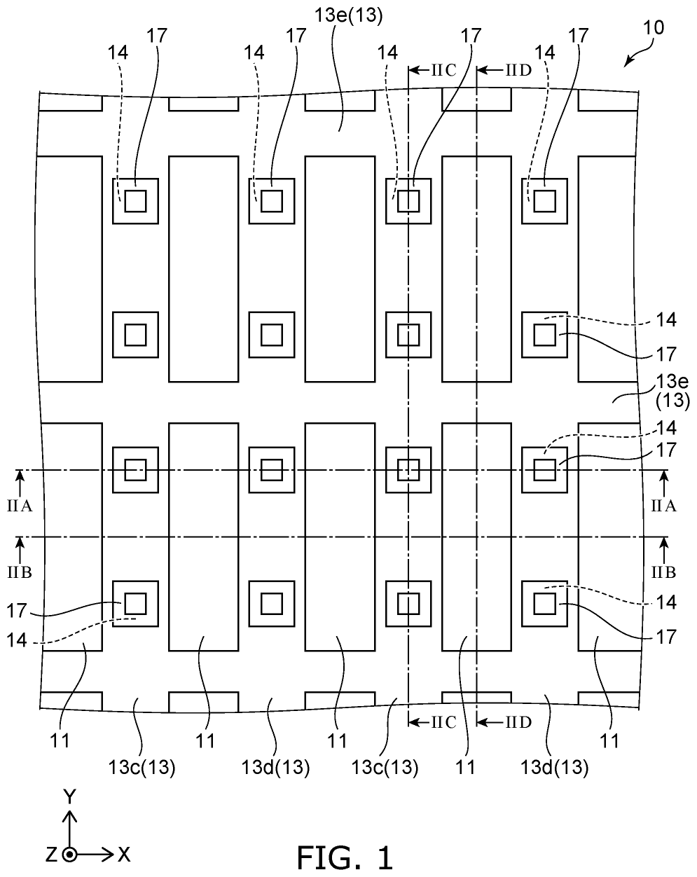

FIG. 1 is a plan view showing a method of manufacturing a light emitting module according to this embodiment.

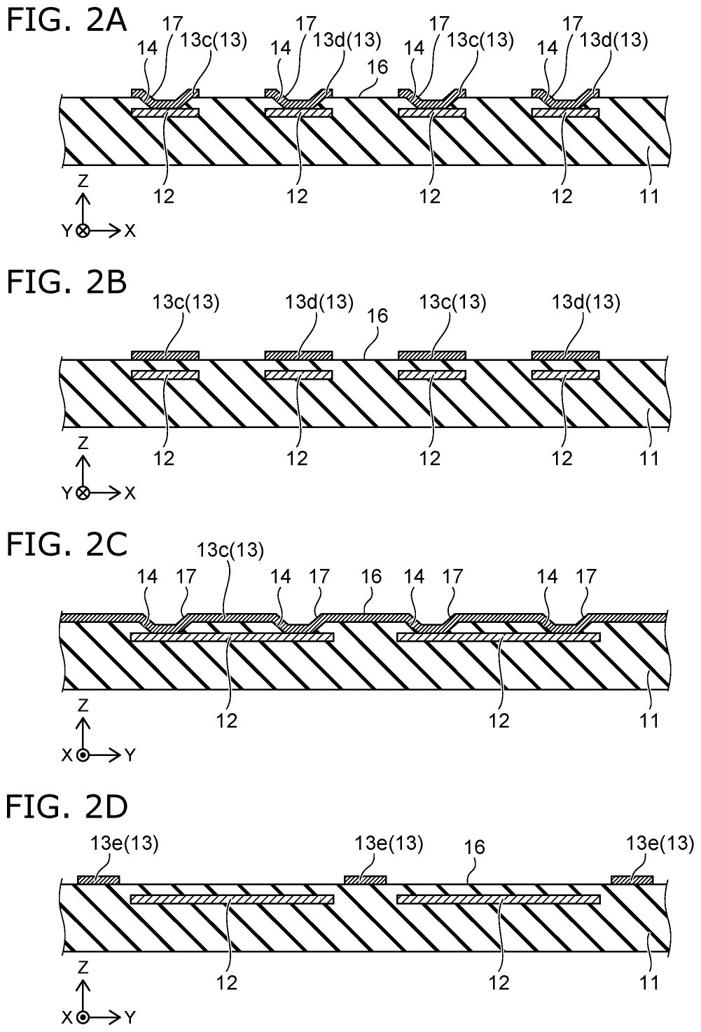

FIG. 2A is an end view taken along line IIA-IIA in FIG. 1.

FIG. 2B is an end view taken along line IIB-IIB in FIG. 1.

FIG. 2C is an end view taken along line IIC-IIC in FIG. 1.

FIG. 2D is an end view taken along line IID-IID in FIG. 1.

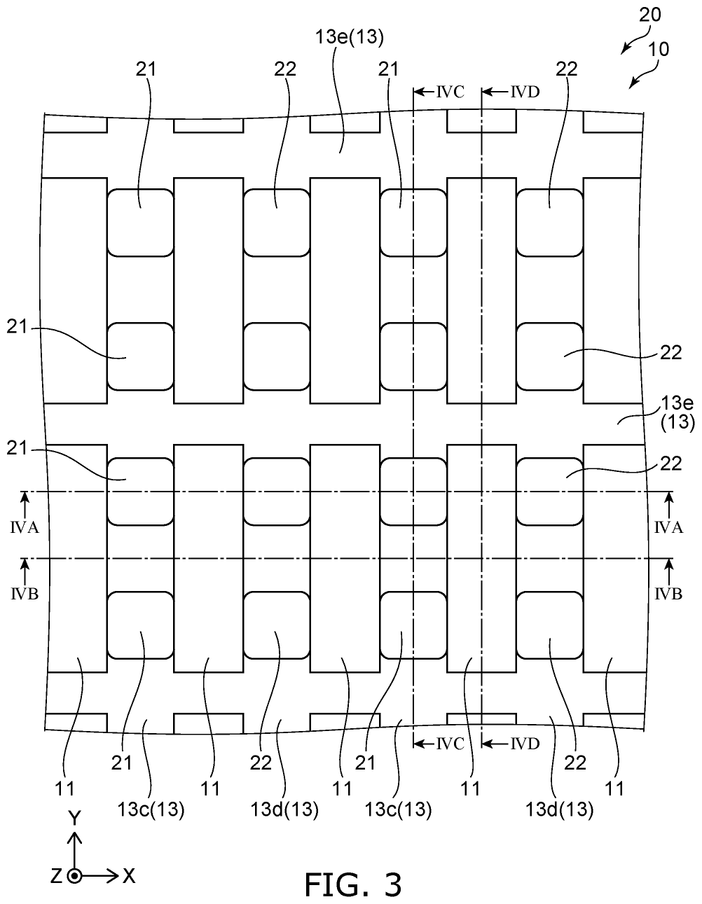

FIG. 3 is a plan view showing the method of manufacturing a light emitting module according to the first embodiment.

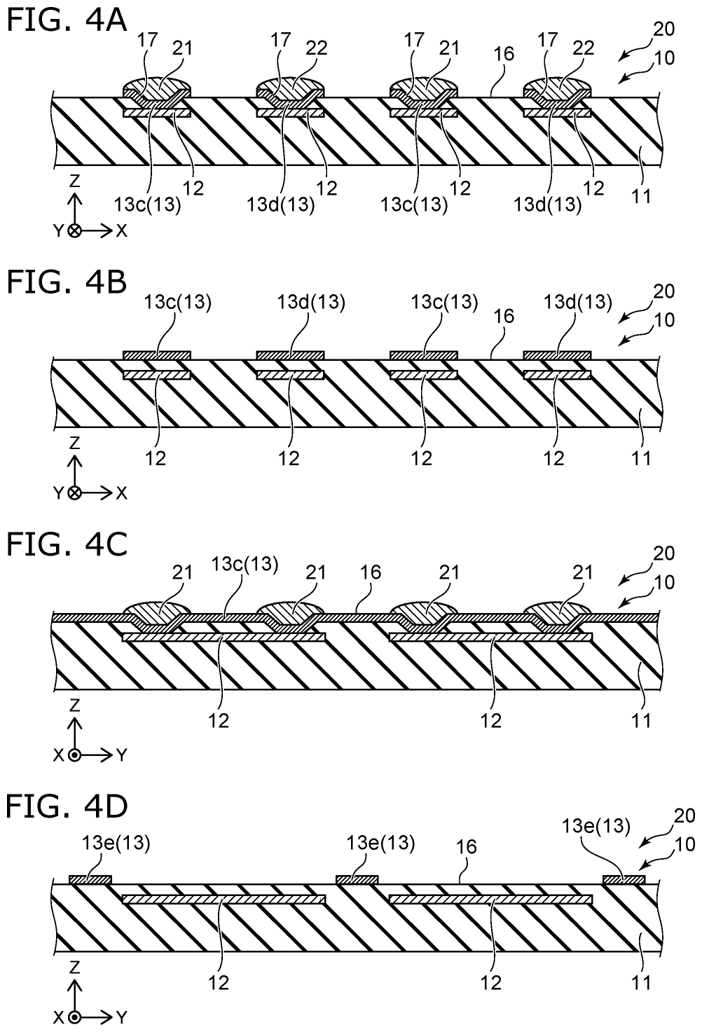

FIG. 4A is an end view taken along line IVA-IVA in FIG. 3.

FIG. 4B is an end view taken along line IVB-IVB in FIG. 3.

FIG. 4C is an end view taken along line IVC-IVC in FIG. 3.

FIG. 4D is an end view taken along line IVD-IVD in FIG. 3.

A wiring board 10 is provided as shown in FIG. 1 to FIG. 2D. The wiring board 10 has a base 11, wiring 12, and a metal layer 13. The wiring board 10 is, for example, an ASIC (application specific integrated circuit) board. The wiring board 10 has an upper surface 16.

A wiring 12 in a form of a multilayer is disposed in the base 11. In FIG. 2A to FIG. 2D, only the uppermost layer of the wiring 12 is shown, and the other layers of the wiring 12 are omitted. The same applies to the other end views described later. A plurality of first recesses 14 are formed in the upper surface of the base 11 for exposing the wiring 12 from the base 11. In a plan view, the first recesses 14 are arranged, for example, in a matrix. At the bottom of each first recess 14, the wiring 12 is exposed from the base 11. A plan view shape of each first recess 14 is quadrangular. The plan view shape of each first recess 14 may be a polygon, such as a triangle, quadrangle, hexagon, or the like, a circle, ellipse, or any other shape. Furthermore, the shape may be a polygon with rounded corners.

In the present specification, an XYZ orthogonal coordinate system is employed for explanation purposes. The directions in which the first recesses 14 are arranged are designated as “X direction” and “Y direction.” The thickness direction of the wiring board is designated as “Z direction.” In the Z direction, a side on which the first recesses 14 are provided may also be referred to as the “upper” side and a side opposite thereto may also be referred to as the “lower” side. These expressions are used for convenience's sake, and are irrespective of the direction of gravity. A “plan view” in the present specification refers to a view when viewing an object from above the object (downward in Z direction).

The metal layer 13 is disposed on the upper surface 16 of the wiring board 10. The material for the metal layer 13 is, for example, one or more selected from the group consisting of tungsten (W), copper (Cu), nickel (Ni), silver (Ag), gold (Au), palladium (Pd), and platinum (Pt), or their alloys. For example, from the heat dissipation standpoint, copper is preferably used for the metal layer 13.

The metal layer 13 in a plan view is, for example, lattice shaped including multiple strip shaped first portions 13c and second portions 13d extending in the Y direction, and multiple strip shaped third portions 13e extending in the X direction. The first portions 13c and the second portions 13d are alternately arranged in the X direction and spaced apart from one another in the X direction. The first portions 13c and the second portions 13d cover the first recesses 14 that are arranged in rows in the Y direction. The metal layer 13 covers the first recesses 14 and is connected to the wiring 12 exposed at the bottom of each first recess 14.

Accordingly, the metal layer 13 can be used as a seed layer for forming the first conducting members 21, the second conducting members 22, the first bonding members 51, and the second bonding members 52 described later by electroplating. In the present specification, the term “connect” refers to electric connection unless otherwise specifically stated. The thickness of the metal layer 13, i.e., the length in the Z direction, is large enough to function as a seed layer for electroplating. Considering the ease of etching of the seed layer subsequent to electroplating, the thickness can be, for example, 100 nm to 500 nm. Second recesses 17 that have similar shapes to the first recesses 14 are provided on the upper surface of the metal layer 13 that covers the first recesses 14. In a plan view, the first recesses 14 overlap the second recesses 17.

Next, as shown in FIG. 3 to FIG. 4D, first conducting members 21 and second conducting members 22 are disposed on the metal layer 13. Each of the first conducting members 21 and each of the second conducting members 22 are disposed to cover respective ones of the second recesses 17. The first conducting members 21 are disposed on and in contact with the first portions 13c. The second conducting members 22 are disposed on and in contact with the second portions 13d. The material for the first conducting members 21 and the second conducting members 22 is, for example, one or more metals selected from the group consisting of tungsten (W), copper (Cu), nickel (Ni), silver (Ag), gold (Au), palladium (Pd), and platinum (Pt), or their alloys. For example, from the heat dissipation standpoint, copper is preferably used as the material for the first conducting members 21 and the second conducting members 22.

The first conducting members 21 and the second conducting members 22 can be formed by plating, for example, wet plating, such as electroplating or electroless plating, or dry plating, such as sputtering or vapor deposition. Among these, electroplating is preferable. Electroplating can increase production efficiency because of the high plating rate.

A plurality of first conducting members 21 are arranged on the first portions 13c of the metal layer 13 along the Y direction. A plurality of second conducting members 22 are arranged on the second portions 13d of the metal layer 13 along the Y direction. In a plan view, the outer edges of the first conducting members 21 at both ends in the X direction substantially coincide with the outer edges of the first portions 13c, and the outer edges of the second conducting members 22 at both ends in the X direction substantially coincide with the outer edges of the second portions 13d.

The first conducting members 21 and the second conducting members 22 are preferably greater in thickness than the depth of the second recesses 17. The depth of a second recess 17 is the height, i.e., the length in the Z direction, from the bottom of the second recess 17 to the upper surface of the metal layer 13 that surrounds the second recess 17. This can position the upper ends of the first conducting members 21 and the upper ends of the second conducting member 22 higher than the upper surface of the metal layer 13. In the example shown in FIG. 3 to FIG. 4D, each of the first conducting members 21 and the second conducting members 22 has a lower part of a shape that reflects a second recess 17 such as a truncated quadrangular pyramid, for example, and an upper part of a hemispheric or semi-elliptic shape with a raised central part.

The plan view shape of each of the first conducting members 21 and the second conducting members 22 is, for example, substantially quadrangular with rounded corners. Furthermore, in a plan view, a second recess 17 is located inward of an outer periphery of each of the first conducting members 21 and the second conducting members 22 preferably encloses. Specifically, at least the edges of each of the first conducting members 21 and the second conducting members 22 in a plan view are preferably disposed on the upper surface of the metal layer 13 that surrounds a second recess 17 in part or whole. This allows the first conducting members 21 and the second conducting members 22 to fill the second recesses 17 of the metal layer 13.

An intermediate structure 20 is provided as described above. The intermediate structure 20 includes a wiring board 10, first conducting members 21, and second conducting members 22. The wiring board 10 has an upper surface 16 and includes a metal layer 13 disposed on the upper surface 16. Each of the first conducting members 21 is disposed on and in contact with a corresponding one of the first portions 13c of the metal layer 13. Each of the second conducting members 22 is disposed on and in contact with a corresponding one of the second portions 13d of the metal layer 13. Each first conducting member 21 and each second conducting member 22 are located apart from each another. The intermediate structure 20 may be provided through manufacturing or purchase. In the case of manufacturing an intermediate structure 20, it may be manufactured by the method described above or another method.

### Step of Disposing Resist Layer

A resist layer 30 is disposed on the intermediate structure 20.

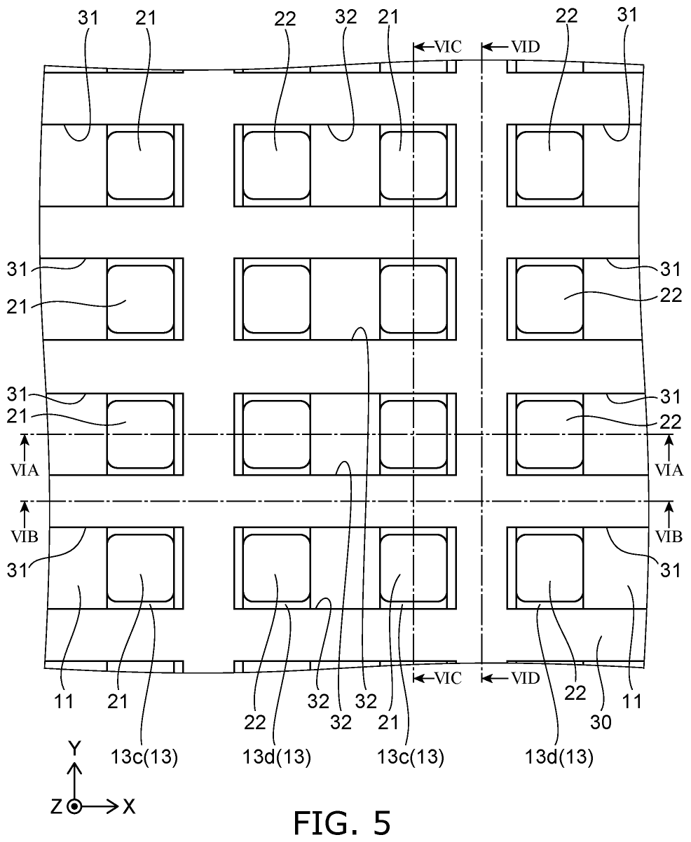

FIG. 5 is a plan view showing the method of manufacturing a light emitting module according to this embodiment.

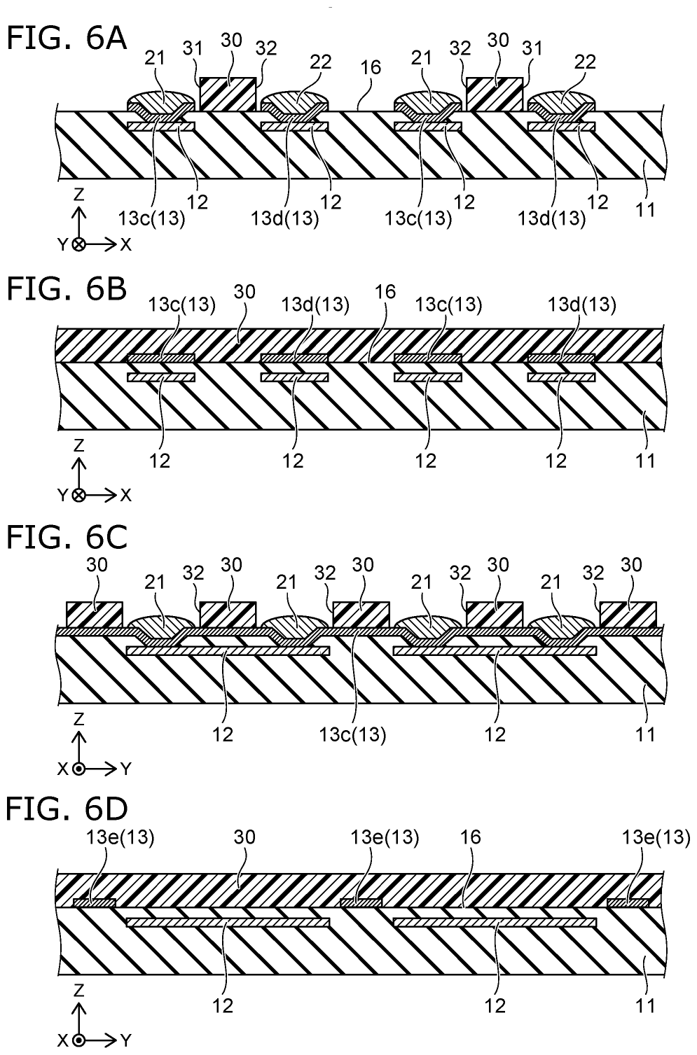

FIG. 6A is an end view taken along line VIA-VIA in FIG. 5.

FIG. 6B is an end view taken along line VIB-VIB in FIG. 5.

FIG. 6C is an end view taken along line VIC-VIC in FIG. 5.

FIG. 6D is an end view taken along line VID-VID in FIG. 5.

The resist layer 30 is formed, for example, by photolithography. As shown in FIG. to FIG. 6D, the resist layer 30 is lattice shaped in the plan view, for example, and has first openings 31 and second openings 32 arranged in a matrix. The first openings 31 and the second openings 32 extend through the resist layer 30 in the Z direction. In the resist layer rows of first openings 31, each row extending along the Y direction, and rows of second openings 32, each row extending along the Y direction, are alternately arranged in the X direction.

A single first conducting member 21 and a single second conducting member 22 are exposed in each of the first and second openings 31 and 32. In each opening, the first conducting member 21 and the second conducting member 22 are disposed near both ends of respective ones of openings in the X direction. In other words, the resist layer 30 is disposed on the intermediate structure 20 such that a periphery of each opening of the first and second openings 31 and 32 collectively surrounds a single first conducting member 21 and a single second conducting member 22 that are adjacent in the X direction in the plan view.

Accordingly, each of the first and second conducting members 21 and 22 is surrounded by the resist layer 30 on three sides (i.e., one side in the X direction and both sides in the Y direction), and not surrounded on the other side in the X direction. As used herein, the phrase “surrounded by the resist layer 30” refers to being proximate to the periphery of an opening of the resist layer 30 in a plan view. For example, the distance between the resist layer 30 and a first conducting member 21 or second conducting member 22 is equal to or less than the thickness of the resist layer 30. The resist layer 30 may be in contact with the first conducting members 21 and the second conducting members 22 along the three sides where the first conducting members 21 and the second conducting members 22 are proximate to the resist layer.

The thickness of the resist layer 30 is preferably greater than the distance from the upper surface of the metal layer 13 located around a second recess 17 to the upper ends of the first conducting members 21 and the second conducting members 22. The thickness of the resist layer 30 is preferably set as 1.4 to 2.6 times the thickness of the first conducting members 21 and the second conducting members 22. For example, the thickness of the resist layer 30 is set to 3.5 μm to 4.0 μm.

### Step of Disposing Light Emitting Element on Resist Layer

Next, light emitting elements 40 are disposed on the resist layer 30.

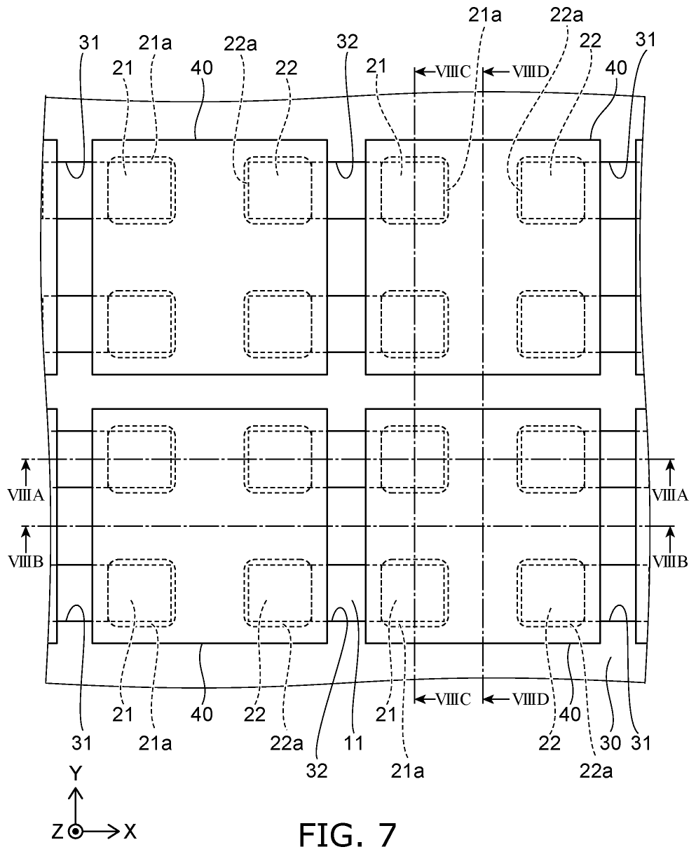

FIG. 7 is a plan view showing the method of manufacturing a light emitting module according to this embodiment.

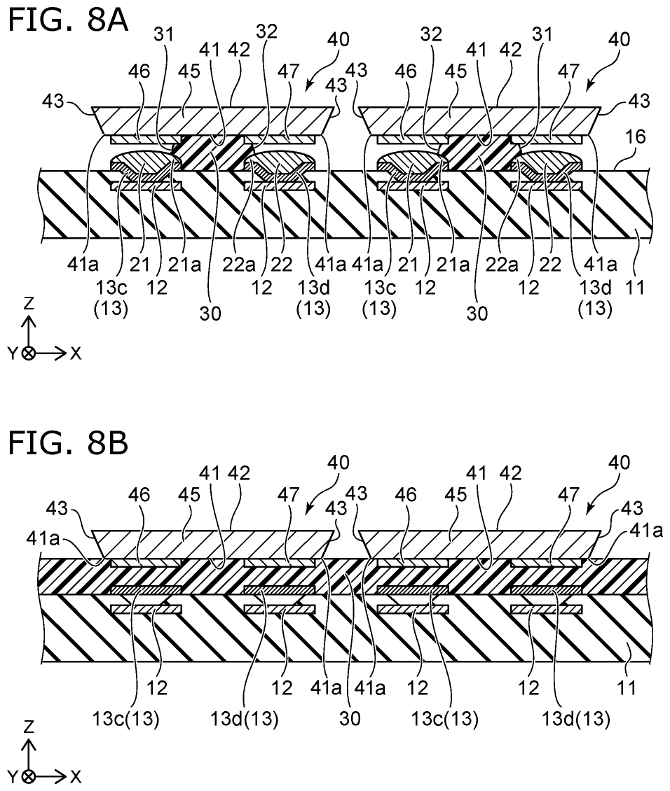

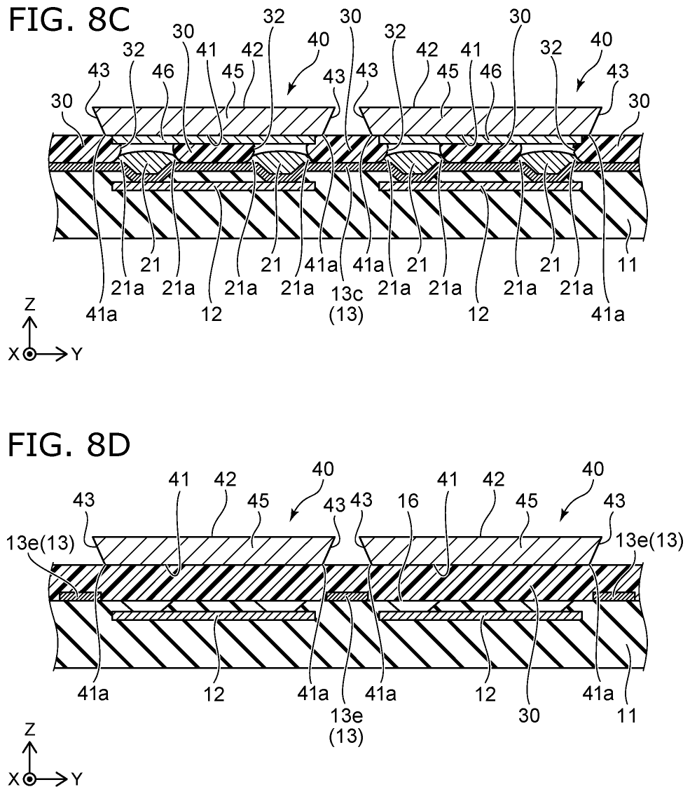

FIG. 8A is an end view taken along line VIIIA-VIIIA in FIG. 7.

FIG. 8B is an end view taken along line VIIIB-VIIIB in FIG. 7.

FIG. 8C is an end view taken along line VIIIC-VIIIC in FIG. 7.

FIG. 8D is an end view taken along line VIIID-VIIID in FIG. 7.

As shown in FIG. 7 to FIG. 8D, light emitting elements 40 are provided. Light emitting elements 40 are, for example, light emitting diodes (LEDs). The shape of a light emitting element 40 can be a truncated quadrangular pyramid shape or a rectangular-parallelepiped shape. When a light emitting element 40 is a truncated quadrangular pyramid shape or a rectangular-parallelepiped shape, the light emitting element 40 has a lower surface 41, an upper surface 42 opposing the lower surface 41, and four lateral surfaces 43 between the lower surface 41 and the upper surface 42. The outer periphery of the lower surface 41 has a rectangular shape. For example, the light emitting element 40 has a truncated quadrangular pyramid shape in which the upper surface 42 is larger than the lower surface 41. The light emitting element 40 includes a semiconductor stack structure 45, a first electrode 46, and a second electrode 47. The first electrode 46 and the second electrode 47 are disposed apart from one another on the lower surface 41.

Next, the light emitting elements 40 are disposed on the resist layer 30. Each light emitting element 40 is disposed on the resist layer 30 such that at least one lattice point of the lattice shape of the resist layer 30 is in contact with the lower surface of the light emitting element 40. At this point, the first electrode 46 of the light emitting element 40 faces a portion of the first conducting member 21 exposed from the resist layer in the first opening 31, and the second electrode 47 faces a portion of the second conducting member 22 exposed from the resist layer 30 in the second opening 32. Each light emitting element 40 is supported by the resist layer 30, and apart from the intermediate structure 20. In other words, the first electrode 46 of the light emitting element 40 is apart from the first conducting member 21 of the intermediate structure 20 in the Z direction, and the second electrode 47 is apart from the second conducting member 22 in the Z direction.

Each light emitting element 40 is disposed such that portions of the outer periphery 41a of the lower surface 41 of the light emitting element 40 are exposed from the resist layer in the first opening 31 and the second opening 32 of the resist layer 30. Specifically, when the shape of the outer periphery 41a of the lower surface 41 of the light emitting element 40 is quadrangular, the light emitting element is disposed on the resist layer 30 such that two opposing sides among four sides of the rectangle (e.g., the two sides extending in the X direction) are entirely in contact with the resist layer 30 while portions of the other two opposing sides (e.g., the two sides extending in the Y direction) are exposed from the resist layer 30 in the first opening 31 and the second opening 32.

When disposing the light emitting elements 40 on the resist layer 30, the resist layer is preferably pressed with the light emitting elements 40. This can more firmly fix the light emitting elements 40 onto the resist layer. Furthermore, pressing the resist layer 30 in the Z direction at this time allows the resist layer 30 to spread across the XY plane, which reduces the areas of the first openings 31 and the second openings 32. As a result, the resist layer 30 covers portions 21a of the end portions of the first conducting members 21 and portions 22a of the end portions of the second conducting members 22. Specifically, with respect to each of the first conducting members 21 and the second conducting members 22, the end portions along the three sides that are surrounded by the resist layer 30, i.e., one side in the X direction and both sides in the Y direction, are covered by the resist layer 30, and the end portion of the other side in the X direction remains not covered by the resist layer 30. In other words, in each of the first conducting members 21 and the second conducting members 22, the end portions along one side in the X direction and both sides in the Y direction are in contact with the resist layer 30, and the end portion along the other side in the X direction is apart from the resist layer 30.

### Step of Forming First Bonding Member and Second Bonding Member

Next, first bonding members 51 and second bonding members 52 are formed. Specifically, on each of the first conducting members 21, a first bonding member 51 is formed to be in contact with the first conducting member 21 and a first electrode 46, and on each of the second conducting members 22, a second bonding member 52 is formed to be apart from the first bonding member 51 and in contact with the second conducting member 22 and a second electrode 47.

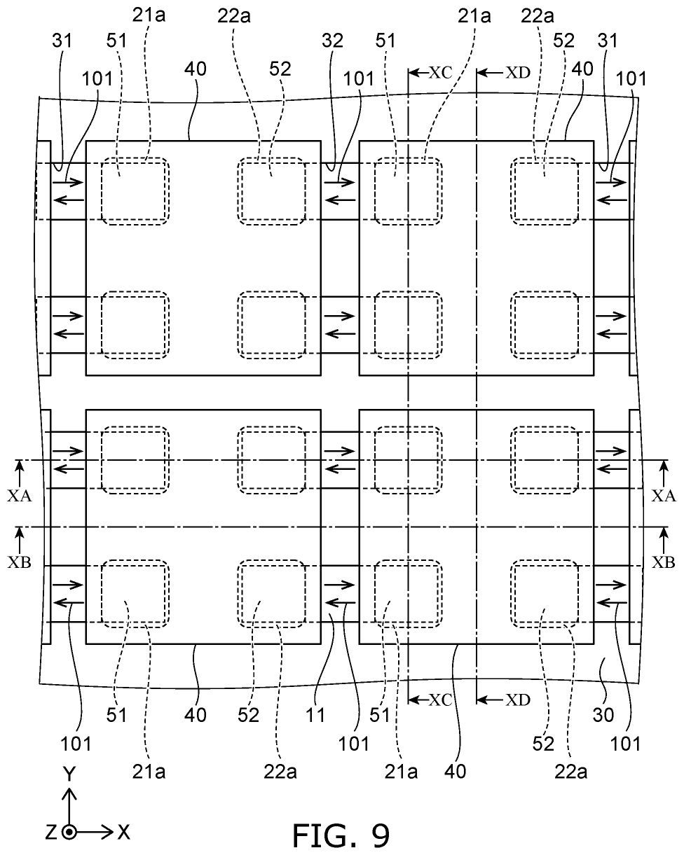

FIG. 9 is a plan view showing the method of manufacturing a light emitting module according to this embodiment.

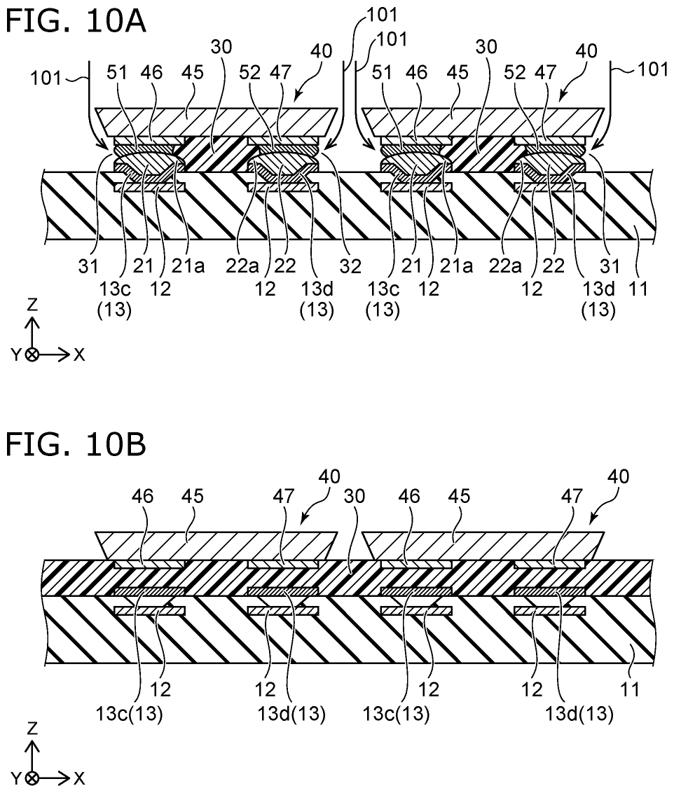

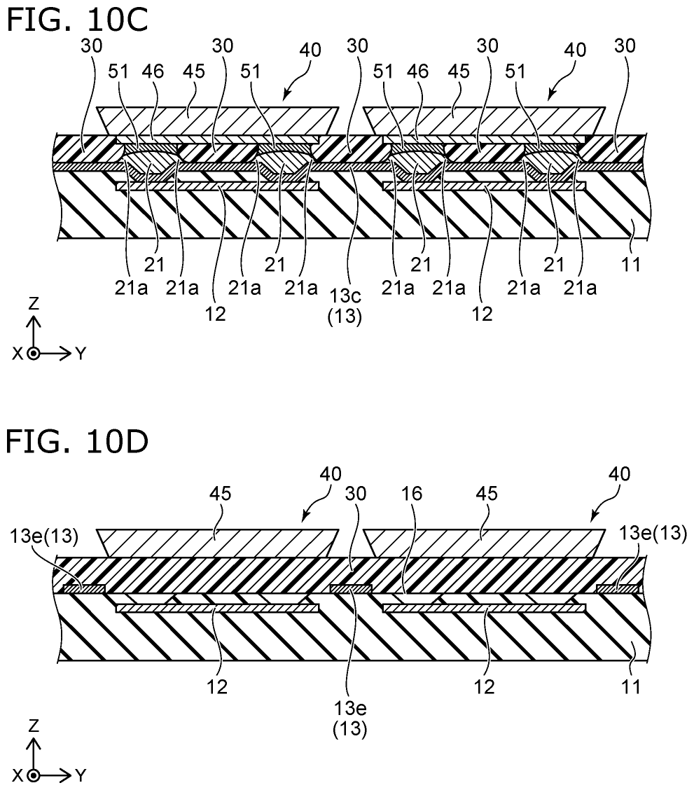

FIG. 10A is an end view taken along line XA-XA in FIG. 9.

FIG. 10B is an end view taken along line XB-XB in FIG. 9.

FIG. 10C is an end view taken along line XC-XC in FIG. 9.

FIG. 10D is an end view taken along line XD-XD in FIG. 9.

As shown in FIG. 9 to FIG. 10D, first bonding members 51 are formed on the first conducting members 21, and second bonding members 52 are formed on the second conducting members 22. The material for the first bonding members 51 and the second bonding members 52 can be, for example, one or more metals selected from the group consisting of tungsten (W), copper (Cu), nickel (Ni), silver (Ag), gold (Au), palladium (Pd), and platinum (Pt), or their alloys. Similar to the first conducting members 21 and the second conducting members 22, from the heat dissipation standpoint, copper is preferably used as the material for the first bonding members 51 and the second bonding members 52.

The first bonding members 51 and the second bonding members 52 can be formed by electroplating. When forming the first bonding members 51 and the second bonding members 52 by electroplating, the metal layer 13, the first conducting members 21, and the second conducting members 22 serve as the seed layers for electroplating. The plating solution 101 penetrates the gaps between adjacent light emitting elements in the X direction into the first openings 31 and the second openings 32 to come into contact with the first conducting members 21 and the second conducting members 22.

The plating growth of the first bonding members 51 originates from the first conducting members 21 to reach the first electrodes 46 of the light emitting elements 40. This can bring the first bonding members 51 into contact with the first conducting members 21 and the first electrodes 46. The plating growth of the second bonding members 52 originates from the second conducting members 22 to reach the second electrodes 47 of the light emitting elements 40. Accordingly, the second bonding members 52 can be in contact with the second conducting members 22 and the second electrodes 47.

Some regions of the upper surface of the intermediate structure 20 where the first conducting members 21 are spaced apart from the second conducting members 22 are covered by the resist layer 30, so that the plating solution 101 does not enter these regions. The plating solution 101 enters other regions exposed from the resist layer 30, i.e., the first openings 31 and the second openings 32. However, no metal layer 13 is disposed in the regions in the first openings 31 and the second openings 32 where the first conducting members 21 are spaced apart from the second conducting members 22. In other words, no origins for plating growth are provided in the regions in the first openings 31 and the second openings 32 where the first conducting members 21 are isolated from the second conducting members 22. Thus, growth of the first bonding members 51 originating from the first conducting members 21 and growth of the second bonding members 52 originating from the second conducting members 22 can be caused at locations spaced apart from each other.

The portions 21a of the end portions of the first conducting members 21, which are covered by the resist layer 30 that serves as a mask, do not come into contact with the plating solution, so that no first bonding member 51 grows on the portions 21a. Similarly, no second bonding member 52 grows on the portions 22a of the second conducting members 22 that are covered by the resist layer 30. Accordingly, in a plan view, the portions 21a at the end portions of the first conducting members 21 are exposed from respective first bonding members 51, and the portions 22a at the end portions of the second conducting members 22 are exposed from respective second bonding members 52.

In the manner described above, an intermediate structure that includes a wiring board 10, a resist layer 30, light emitting elements 40, first bonding members 51, and second bonding members 52 is obtained.

### Step of Removing Resist Layer

Then, the resist layer 30 is removed.

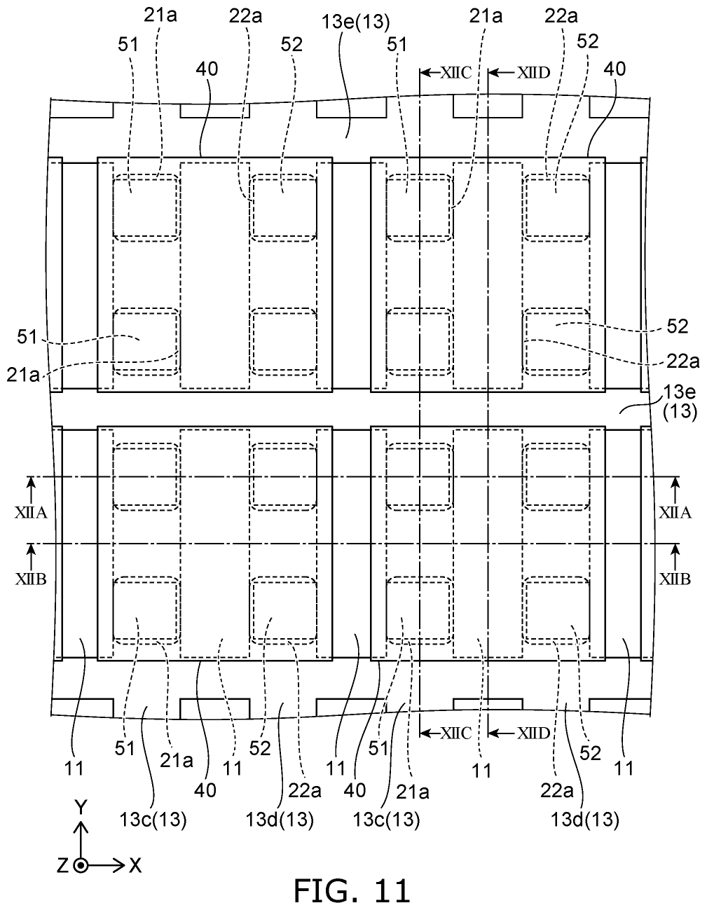

FIG. 11 is a plan view showing the method of manufacturing a light emitting module according to this embodiment.

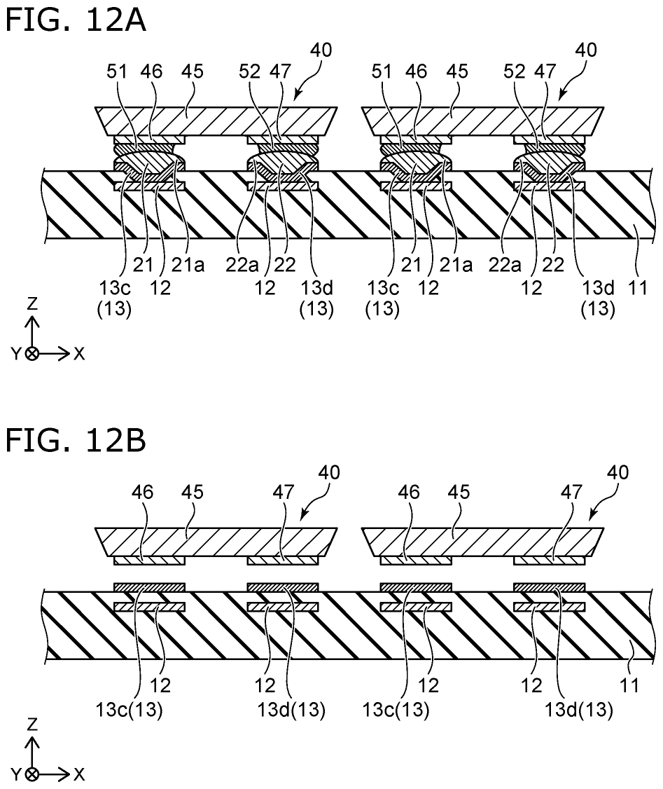

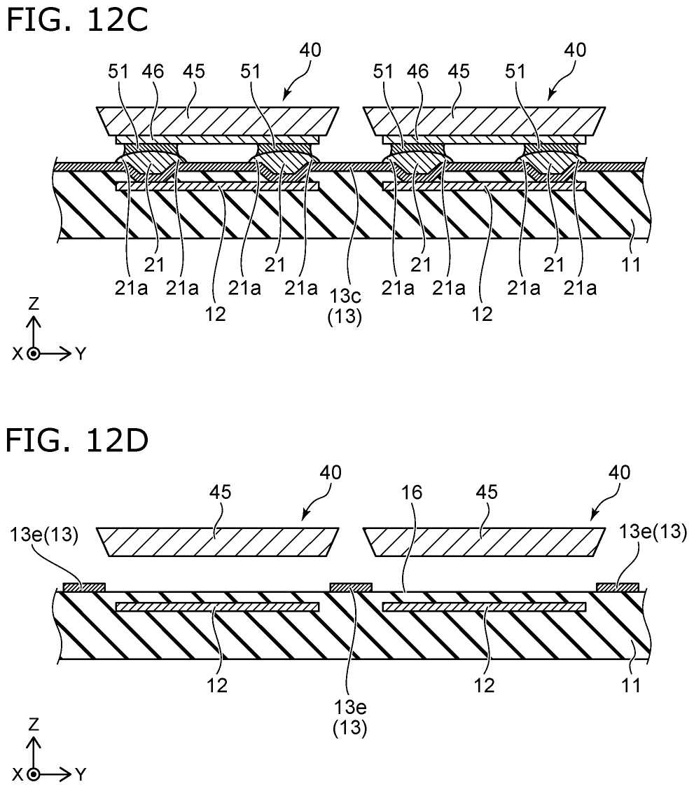

FIG. 12A is an end view taken along line XIIA-XIIA in FIG. 11.

FIG. 12B is an end view taken along line XIIB-XIIB in FIG. 11.

FIG. 12C is an end view taken along line XIIC-XIIC in FIG. 11.

FIG. 12D is an end view taken along line XIID-XIID in FIG. 11.

The resist layer 30 is removed, for example, by immersing the intermediate structure obtained by following the steps described above in a resist stripping solution. This allows for exposing the surfaces of the first conducting members 21, the second conducting members 22, the first bonding members 51, the second bonding members 52, the first electrodes 46, and the second electrodes 47 that have been in contact with the resist layer 30 as shown in FIG. 11 to FIG. 12D.

### Step of Separating Metal Layer

Next, the metal layer 13 is separated into a first metal layer 13a and a second metal layer 13b.

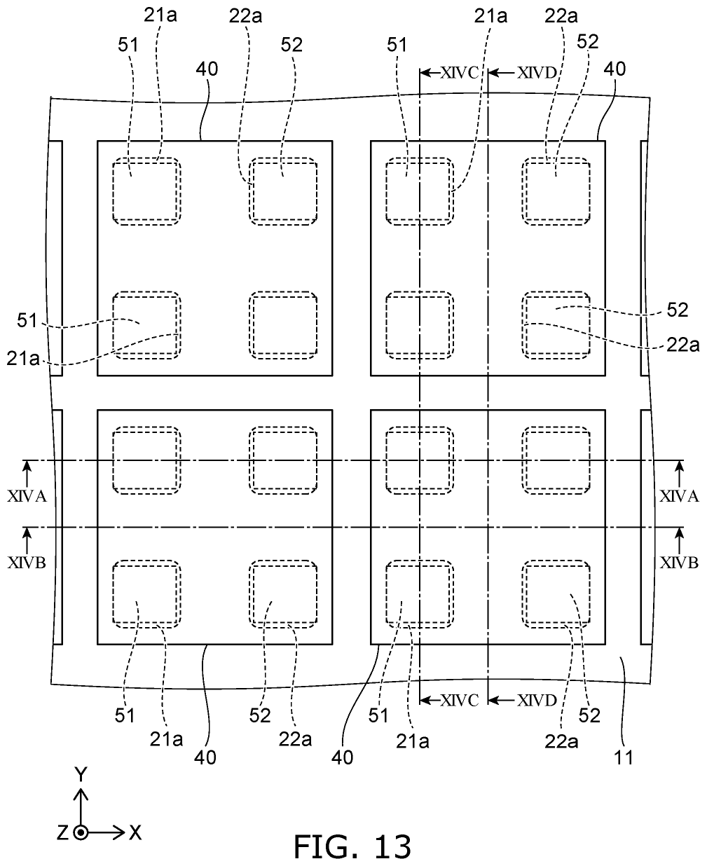

FIG. 13 is a plan view showing the method of manufacturing a light emitting module according to this embodiment.

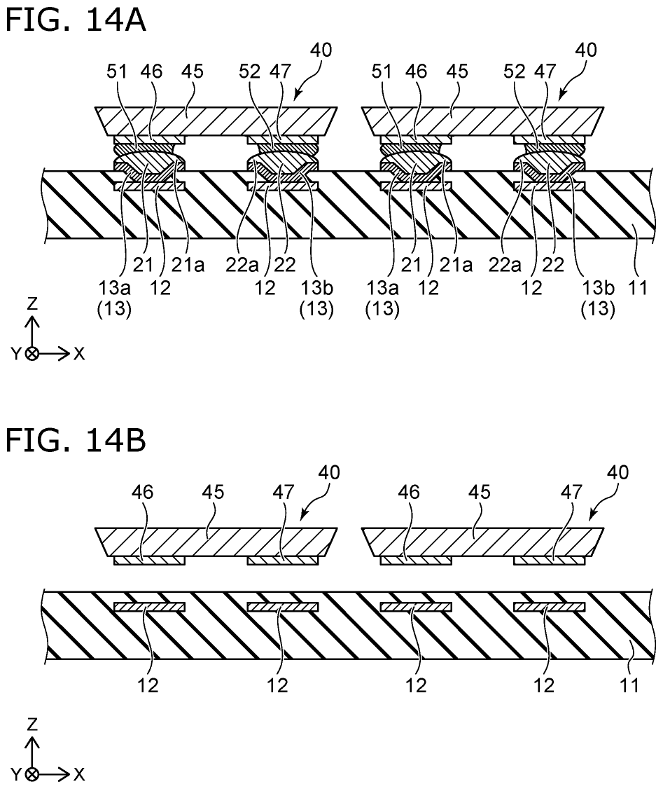

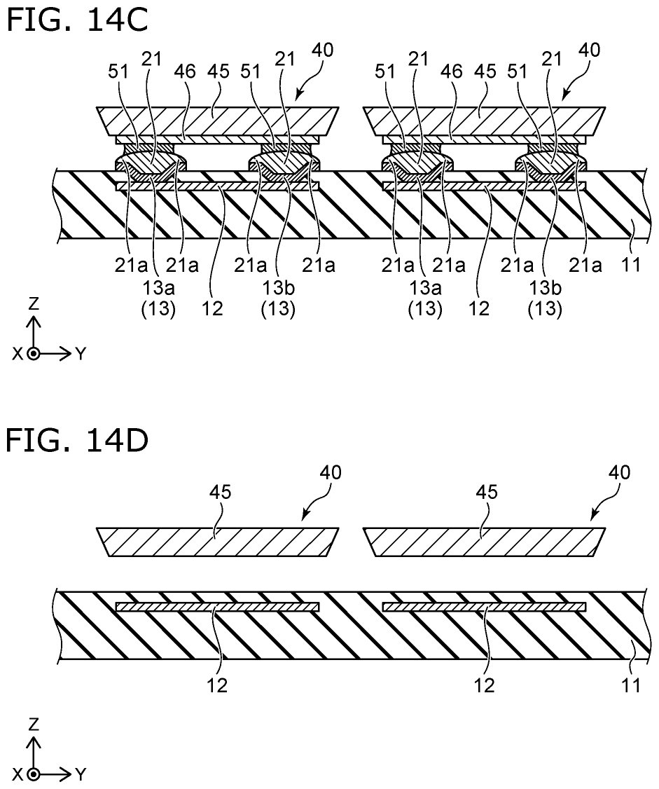

FIG. 14A is an end view taken along line XIVA-XIVA in FIG. 13.

FIG. 14B is an end view taken along line XIVB-XIVB in FIG. 13.

FIG. 14C is an end view taken along line XIVC-XIVC in FIG. 13.

FIG. 14D is an end view taken along line XIVD-XIVD in FIG. 13.

In the example herein, portions of the metal layer 13 are removed, so that the metal layer 13 can be separated into a first metal layer 13a and a second metal layer 13b. Specifically, the metal layer 13 is selectively removed using the first conducting members 21 and the second conducting members 22 as a mask, so that the metal layer 13 is separated into the first metal layer 13a in contact with the first conducting members 21 and the second metal layer 13b in contact with the second conducting members 22. The removal of the metal layer 13 can be performed by etching, for example, wet etching. This allows for selectively removing the metal layer 13 as shown in FIG. 13 to FIG. 14D. In other words, the portions of the metal layer 13 covered by the first conducting members 21 and the second conducting members 22 remain in place, and the other portion removed. At this time, a portion of each first conducting member 21, a portion of each second conducting member 22, a portion of each first bonding member 51, and a portion of each second bonding member 52 are also etched off. The metal layer 13 can be selectively removed because the thickness of the metal layer 13 is sufficiently lesser than the lengths of these members in the X and Y directions. The thickness of the metal layer 13 is, for example, equal to or less than one third of the lengths of the first bonding members 51 and the second bonding members 52 in the X and Y directions.

In the manner described above, the metal layer 13 is separated into the first metal layer 13a contacting the first conducting members 21 and the second metal layer 13b contacting the second conducting members 22. More specifically, in a plan view, each first portion 13c of the lattice shaped metal layer 13 extending in the Y direction is separated into the first metal layer 13a disposed at a plurality of locations, and each second portion 13d extending in the Y direction is separated into the second metal layer 13b disposed at a plurality of locations. The third portions 13e extending in the X direction are removed entirely. Because the first portions 13c and the second portions 13d have been connected by the third portions 13e, removing the third portions 13e causes the first metal layer 13a disposed at each location and the second metal layer 13b disposed at each location to be spaced apart from each other In this manner, first conductive parts, each including a first metal layer 13a, a first conducting member 21, a first bonding member 51, and a first electrode 46, and second conductive parts, each including a second metal layer 13b, a second conducting member 22, a second bonding member 52, and a second electrode 42, can be arranged on the upper surface of the wiring board, each first conductive part and each second conductive part spaced apart from each other.

### Step of Forming Metal Film

Next, metal films 60 are formed.

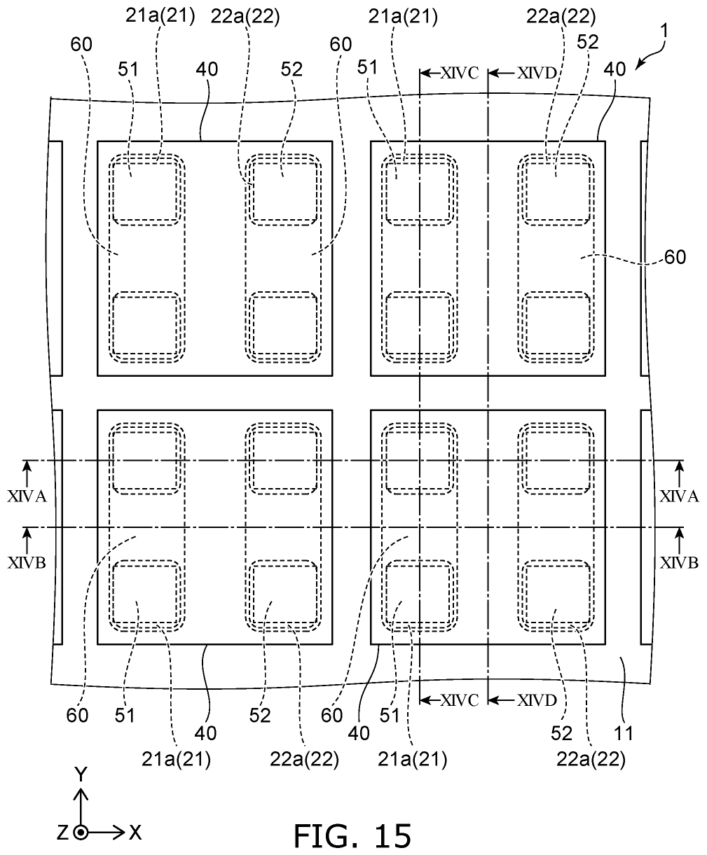

FIG. 15 is a plan view showing the method of manufacturing a light emitting module according to this embodiment.

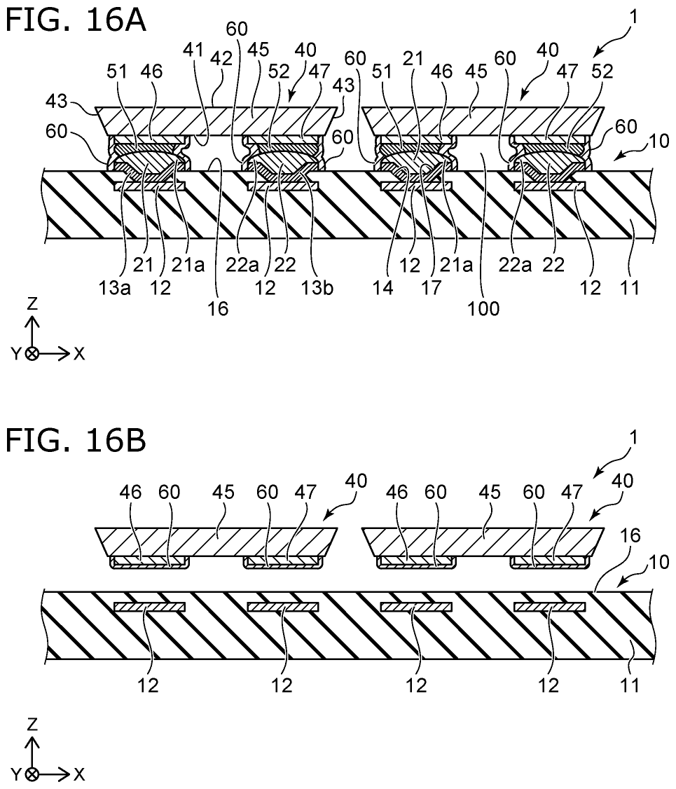

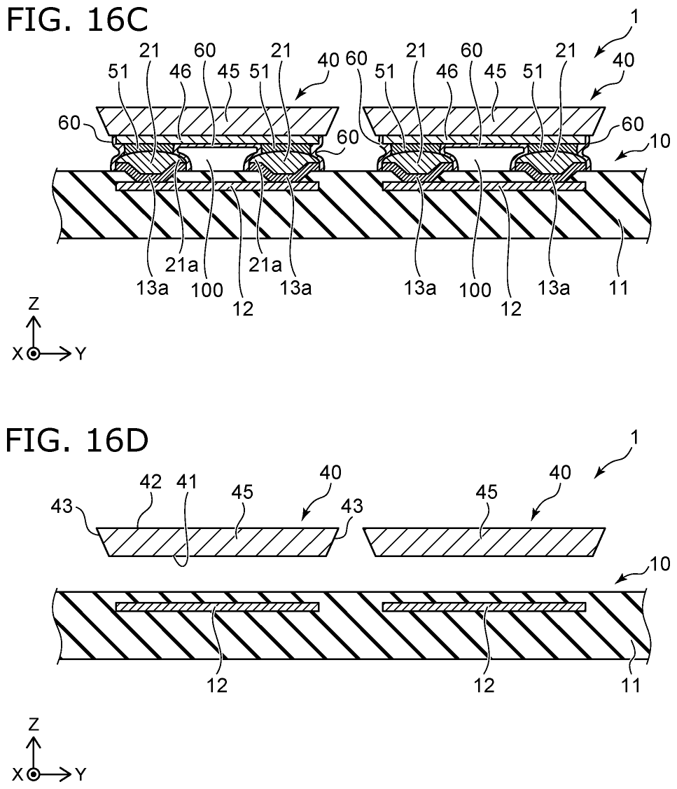

FIG. 16A is an end view taken along line XVIA-XVIA in FIG. 15.

FIG. 16B is an end view taken along line XVIB-XVIB in FIG. 15.

FIG. 16C is an end view taken along line XVIC-XVIC in FIG. 15.

FIG. 16D is an end view taken along line XVID-XVID in FIG. 15.

As shown in FIG. 15 to FIG. 16D, each metal film 60 is formed to cover surfaces of the first conductive parts each including a first metal layer 13a, a first conducting member 21, a first bonding member 51, and a first electrode 46 (i.e., the surfaces of these members exposed from other members) or surfaces of the second conductive parts each including a second metal layer 13b, a second conducting member 22, a second bonding member 52, and a second electrode 47 (i.e., the surfaces of these members exposed from other members). The metal film 60 can be formed, for example, by electroless plating. The metal film 60 preferably has a precious metal layer, for example, a gold (Au) layer as the outermost layer. The metal film 60 may be a single-layer gold film, or a multi-layer film of a gold layer and at least one layer made of nickel, silver, palladium, or platinum. Electroless plating of a precious metal can be accomplished by way of a substitution reaction that utilizes an ionization tendency difference or a reduction reaction that uses a catalyst.

Covering the first conductive parts and the second conductive parts with a metal film 60 can protect the first conductive parts and the second conductive parts from the external environment. Specifically, in the case in which the first conductive parts and the second conductive parts contain copper, if exposed, sulfurization of copper might cause discoloration or corrosion. Covering them with a metal film 60 can reduce the exposure of copper to the external environment. The metal film 60 is not formed on the surface of the insulating base 11 of the wiring board 10 or the surfaces of the light emitting elements 40 except for the first electrodes 46 and the second electrodes 47. Accordingly, the first conductive parts and the second conductive parts are never short circuited by the metal film 60. In the manner described above, a light emitting module 1 according to this embodiment is manufactured.

### Light Emitting Module

The constituents of a light emitting module 1 manufactured as above will be explained next.

As shown in FIG. 15 to FIG. 16D, a light emitting module 1 according to this embodiment includes a wiring board 10, first conducting members 21, second conducting members 22, first bonding members 51, second bonding members 52, and light emitting elements 40. In the light emitting module 1, a plurality of light emitting elements 40 are arranged on a single wiring board 10 in a matrix along the X direction and the Y direction. There are gaps between the light emitting elements 40 adjacent in the X direction and the Y direction. The wiring board 10 and the light emitting elements 40 are apart from one another in the Z direction, and the lower surfaces 41 of the light emitting elements oppose the upper surface 16 of the wiring board 10.

The wiring board 10 has a base 11, wiring 12, a first metal layer 13a, and a second metal layer 13b. The wiring 12 is provided in the base 11. A plurality of first recesses 14 are formed in the upper surface of the base 11, and the wiring 12 is exposed at the bottom of each first recess 14. The first metal layer 13a and the second metal layer 13b are disposed on the upper surface 16 of the wiring board 10 and are connected to the wiring 12 at the bottoms of the first recesses 14. A second recess 17 reflecting a shape of the first recess 14 is formed in the upper surface of each of the first metal layer 13a and the second metal layer 13b. In the case where the wiring board 10 includes an insulation film on the upper surface thereof, the first recesses 14 may be holes that extend through the insulation film.

Each light emitting element 40 is, for example, a truncated quadrangular pyramid or a rectangular-parallelepiped shape, and has a lower surface 41, an upper surface 42 opposing the lower surface 41, and lateral surfaces 43 between the lower surface 41 and the upper surface 42. In the example herein, the lower surface 41 and the upper surface 42 are quadrangular and the light emitting element 40 has four lateral surfaces 43. Moreover, each light emitting element 40 has a semiconductor stack structure 45, a first electrode 46, and a second electrode 47. The first electrode 46 and the second electrode 47 are disposed on the lower surface 41 of the light emitting element 40. The lower surface of each light emitting element 40, for example, has one first electrode 46 and one second electrode 47. In this case, in a plan view, the first electrode 46 and the second electrode 47 are apart from one another in the X direction, and the shape of each electrode has a rectangular shape that is greater in length in the Y direction, for example. The first metal layer 13a at two locations that are apart in the Y direction oppose a first electrode 46. The second metal layer 13b at two locations that are apart in the Y direction oppose a second electrode 47. In other words, the first electrode 46 and the first metal layer 13a at two locations, and the second electrode 47 and the second metal layer 13b at two locations, are arranged to respectively overlap in a plan view.

The first conducting members 21, the second conducting members 22, the first bonding members 51, and the second bonding members 52 are disposed between the wiring board 10 and the light emitting elements 40. The first conducting members 21 are disposed on the first metal layer 13a to be in contact therewith. The second conducting members 22 are disposed on the second metal layer 13b to be in contact therewith. The first bonding members 51 are disposed on the first conducting members 21 to be in contact with the first conducting members 21 and the first electrodes 46. The second bonding members 52 are disposed on the second conducting members 22 to be in contact with the second conducting members 22 and the second electrodes 47. The first electrode 46 of each light emitting element 40 is connected to two first bonding members 51, two first conducting members 21, and the first metal layer 13a at two locations. The second electrode 47 of each light emitting element 40 is connected to two second bonding members 52, two second conducting members 22, and the second metal layer 13b at two locations.

Each first conductive part includes the first metal layer 13a at two locations, two first conducting members 21, two first bonding members 51, and one first electrode 46, and each second conductive part includes the second metal layer 13b at two locations, two second conducting members 22, two second bonding members 52, and one second electrode 47. The surfaces of the first conductive parts and the surfaces of the second conductive parts are covered by a metal film 60 that contains a precious metal. On the upper surface of the wiring board 10, the first conductive parts and the second conductive parts are isolated from one another. Between the wiring board 10 and the light emitting elements 40, there is a space 100 that is created by the first conductive parts and the second conductive parts that are isolated from one another. For example, air is present in the space 100.

In a plan view, some of the end portions of the first conducting members 21 are exposed from the first bonding members 51, and some of the end portions of the second conducting members 22 are exposed from the second bonding members 52. In the example shown in FIG. 15 to FIG. 16D, in a plan view, the portions 21a of the first conducting members 21 that are exposed from the first bonding members 51 (the portions 21a at the ends that were previously covered by the resist layer) are located at both sides of the first conducting members 21 in the Y direction and one side in the X direction, and the portions 22a of the second conducting members 22 that are exposed from the second bonding members 52 (the portions 22a at the ends that were previously covered by the resist layer) are located at both sides of the second conducting members 22 in the Y direction and the other side in the X direction. With respect to the first conducting member 21 and the second conducting member 22 connected to one light emitting element 40, in a plan view, the portion 21a and the portion 22a are located between the first bonding member 51 and the second bonding member 52.

### Effects

The effect of this embodiment will be explained next.

In this embodiment, in the step of disposing a resist layer shown in FIG. 5 to FIG. 6D, a lattice-shaped resist layer 30 is disposed, and in the step of disposing light emitting elements on the resist layer shown in FIG. 7 to FIG. 8D, the light emitting elements 40 are disposed on the resist layer 30. This allows the light emitting elements 40 to be stably held. Furthermore, this allows for facilitating the positioning of the light emitting elements 40 on the wiring board 10 while maintaining the distance between the wiring board 10 and the light emitting elements 40.

In the step of forming first bonding members and second bonding members shown in FIG. 9 to FIG. 10D, the first bonding members 51 and the second bonding members 52 are formed in the space surrounded by the resist layer 30 along three sides between the wiring board 10 and the light emitting elements 40. This makes it easy to control the shapes of the first bonding members 51 and the second bonding members 52. Furthermore, exposing the first conducting members 21 and the second conducting members 22 at the first openings 31 and the second openings 32 of the resist layer 30 allows the plating solution 101 to reach the first conducting members 21 and the second conducting members 22.

In this step, moreover, the first bonding members 51 and the second bonding members 52 are respectively grown using the first conducting members 21 and the second conducting members 22 as the originating points. Accordingly, the distances of the growth to the first electrodes 46 and the second electrodes 47 (i.e., the lengths in the Z direction) are shorter than those in the case in which the first metal layer 13a and the second metal layer 13b are used as the originating points.

This can thus efficiently grow the first bonding members 51 and the second bonding members 52 in a short period of time.

In the step of disposing light emitting elements on a resist layer shown in FIG. 7 to FIG. 8D, pressing the light emitting elements 40 into the resist layer 30 deforms the resist layer 30 to allow the resist layer 30 to cover some portions at the ends of the first conducting members 21 and the ends of the second conducting members 22. As a result, subsequent to forming the first bonding members 51 and the second bonding members 52, those portions of the first conducting members 21 are exposed from the first bonding members 51 and those portions of the second conducting members 22 are exposed from the second bonding members 52 in a plan view.

In the step of providing an intermediate structure shown in FIG. 1 to FIG. 2D, in a plan view, the first conducting members 21 and the second conducting members 22 have a shape in which the second recess 17 is located inward of the outer periphery of the first or second conducting member 21 or 22. This can increase the distances from the ends of the first conducting members 21 and the ends of the second conducting members 22 to the first recesses 14. In the step of separating the metal layer shown in FIG. 13 to FIG. 14D, this can reduce the penetration of the etching solution into the interior of the base 11 when etching the metal layer 13 by using the first conducting members 21 and the second conducting members 22 as a mask. This can reduce the damage to the wiring 12 disposed in the base 11.

The first bonding members 51 and the second bonding members 52 are formed to be smaller than the first conducting members 21 and the second conducting members 22 in a plan view. In other words, the first openings 31 and the second openings 32 of the resist layer 30 can be made small. This makes it easy to position the outer edges of the first openings 31 and the second openings 32 to be in contact with the first electrodes 46 and the second electrodes 47 in a plan view when disposing the light emitting elements 40 on the resist layer 30. As a result, the outer edges of the first electrodes 46 and the second electrodes 47 are covered by the resist layer 30. This can reduce the contact made by the first bonding members 51 and the second bonding members 52 with areas other than the first electrodes 46 and the second electrodes 47, thereby improving the connectivity of the first bonding members 51 and the second bonding members 52 with the first electrodes 46 and the second electrodes 47.

As described above, according to this embodiment, a light emitting module 1 can be manufactured highly efficiently. Furthermore, shape variation of each member in the light emitting module 1 can be reduced. Accordingly, a high reliability light emitting module 1 can be produced.

### Second Embodiment

A second embodiment of the present invention will be explained next.

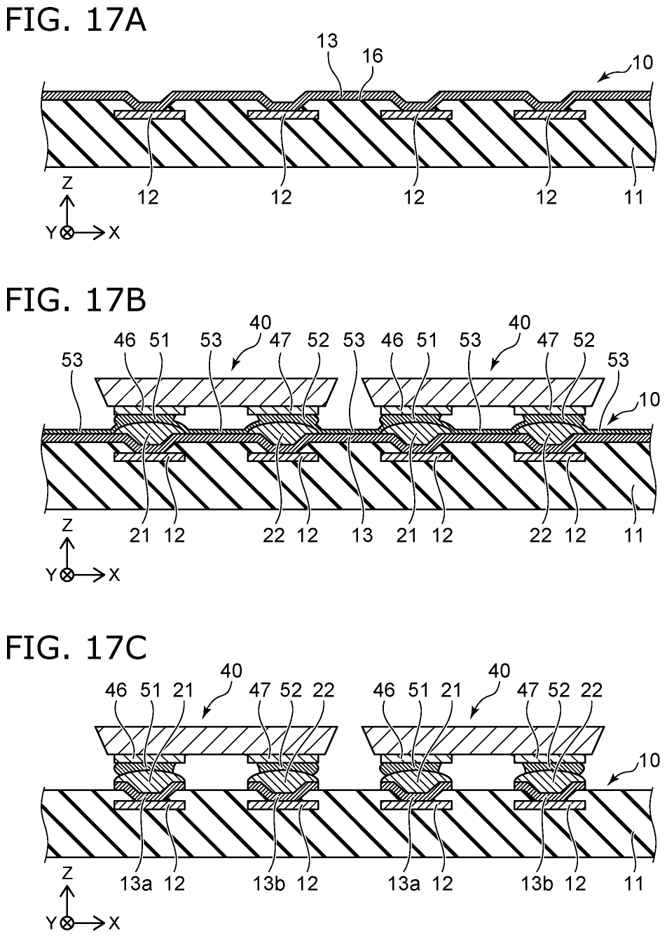

FIG. 17A to FIG. 17C are end views showing a method of manufacturing a light emitting module according to this embodiment.

As shown in FIG. 17A, this embodiment differs from the first embodiment such that the metal layer 13 covers the upper surface of the wiring board 10 entirely. In this embodiment, for example, a wiring board 10 on which a metal layer 13 is disposed across the entire upper surface 16 is provided.

Then the steps shown in FIG. 3 to FIG. 12D are conducted. In other words, an intermediate structure 20 is provided by forming first conducting members 21 and second conducting members 22 on the wiring board 10, followed by forming a resist layer 30 on the intermediate structure 20, disposing light emitting elements 40 on the resist layer 30, forming first bonding members 51 and second bonding members 52, and removing the resist layer 30.

This produces the structure shown in FIG. 17B in which light emitting elements 40 are disposed on a wiring board 10. The metal layer 13 is disposed on the entire upper surface 16 of the wiring board 10. Thus, the plating solution for forming the first bonding members 51 and the second bonding members 52 comes into contact with the metal layer 13 that is exposed from the resist layer 30, thereby forming on the surface of the metal layer 13 third bonding members 53 that link the first bonding members 51 and the second bonding members 52.

Then, as shown in FIG. 17C, the third bonding members 53 and the metal layer 13 are etched off by using the first conducting members 21 and the second conducting members 22 as a mask to thereby remove the third bonding members 53 and separate the metal layer 13 into the first metal layer 13a contacting the first conducting members 21 and the second metal layer 13b contacting the second conducting members 22.

Then the step shown FIG. 15 to FIG. 16D is conducted. In other words, a metal film 60 is formed.

In the manner described above, a light emitting module according to this embodiment is manufactured.

Manufacturing steps and components other than those described above as well as the effect of this embodiment are similar to those in the first embodiment. Variations

The embodiments described above are examples that give shape to the present invention, and the present invention is not limited to these embodiments. For example, any of the embodiments described above to which a certain constituent element or step is added, from which a certain constituent element or step is removed, or in which a certain constituent element or step is modified is encompassed by the present invention.

For example, a metal film 60 does not have to be disposed. Furthermore, the positional relationship between the wiring board 10 and the light emitting elements 40 is not limited to the examples described above. For example, the manner in which the light emitting elements 40 are arranged is not limited to a matrix, and may be arranged in a staggered or hexagonal close-packed manner. The first electrode 46 of each light emitting element 40 may be connected to one first bonding member 51 or three or more first bonding members 51. Furthermore, each light emitting element 40 may have multiple first electrodes 46 each being connected to a different first bonding member 51. The same applies to the second electrodes 47 and the second bonding members 52. Moreover, multiple second recesses 17 may correspond to each of the first conducting members 21 and the second conducting members 22.

For the light emitting elements 40, semiconductor light emitting elements capable of emitting light of any wavelength can be selected. As an example, a blue light emitting element can be used as a light emitting element 40, but is not limited to this. For the light emitting elements 40, those that emit light of a color other than blue light may be used. In the case in which multiple light emitting elements 40 are arranged at certain intervals in a light emitting module 1, those that emit the same color light may be used, or those that emit different color light, such as red, green, or the like, may be used.

For the semiconductor stack structure 45 of a blue light emitting element 40, a nitride-based semiconductor (InₓAl_{y}Ga_{1-x-y}N, 0≤X, 0≤Y, X+Y≤1) can be used. In this case, the semiconductor stack structure 45 includes an emission layer, as well as an n-type semiconductor layer and a p-type semiconductor layer disposed to interpose the emission layer. The n-side electrode and the p-side electrode are electrically connected to the n-type semiconductor layer and the p-type semiconductor layer, respectively. In a plan view, the shape of a light emitting element 40 is not limited to a quadrangle, and may be another polygon, such as a triangle, hexagon, or the like.

Furthermore, a wavelength conversion member containing a phosphor may be disposed on a light emitting element 40. Examples of phosphors include yellow light emitting YAG phosphors (e.g., (Y,Lu,Gd)₃(Al,Ga)₅O₁₂:Ce), green light emitting β-SiAlON phosphors (e.g., (Si,Al)₃(O,N)₄:Eu), red light emitting fluoride based phosphors (e.g., K₂(Si,Ti,Ge)F₆:Mn or K₂ (Si,Al)F₆:Mn), nitride based phosphors (e.g., (Sr,CA)AlSiN₃:Eu), and the like. The wavelength conversion member may contain a single or a plurality of types of phosphors.

Furthermore, a light shielding member may be disposed between adjacent light emitting elements 40. The light shielding member is disposed to enclose a light emitting element 40, covering the lateral surfaces of the light emitting element 40. The light shielding member blocks the propagation of light between adjacent light emitting elements. The light shielding member, moreover, is preferably also disposed in the space 100 between the light emitting elements 40 and the wiring board 10, specifically in the region where the resist layer 30 described above was previously located. The light shielding member is, for example, a resin containing a light reflecting substance. For the light reflecting substance, for example, titanium oxide, aluminum oxide, magnesium oxide, zinc oxide, barium carbonate, barium sulfate, boron nitride, aluminum nitride, glass filler, or the like can be preferably used. For the resin, for example, a silicone resin can be suitably used.

The present invention can be utilized, for example, in automotive headlight, display devices, and the like.

The embodiments of the present invention include Note 1 to Note 10 described below.

### (Note 1)

A method of manufacturing a light emitting module, the method comprising:

Providing an intermediate structure that comprises:
a wiring board having an upper surface and comprising a metal layer disposed at the upper surface,
a first conducting member disposed on the metal layer to be in contact with the metal layer, and
a second conducting member disposed on the metal layer to be in contact with the metal layer and apart from the first conducting member;

disposing, on the intermediate structure, a resist layer having a first opening and a second opening such that the first conducting member is exposed in the first opening and the second conducting member is exposed in the second opening;

providing a light emitting element having a lower surface, the light emitting element comprising a first electrode and a second electrode that are spaced apart from each other at the lower surface, and disposing the light emitting element on the resist layer such that the first electrode and the second electrode respectively face the first conducting member and the second conducting member while a portion of an outer periphery of the lower surface is exposed from the resist layer in the first opening and the second opening;

forming a first bonding member on the first conducting member to be in contact with the first conducting member and the first electrode and forming a second bonding member on the second conducting member to be apart from the first bonding member and in contact with the second conducting member and the second electrode; and

removing the resist layer.

### (Note 2)

The method of manufacturing a light emitting module according to Note 1, wherein, in the step of disposing the light emitting element, the resist layer is pressed by the light emitting element to thereby cover portions at an end of the first conducting member and portions at an end of the second conducting member.

### (Note 3)

The method of manufacturing a light emitting module according to Note 1 or 2 further comprising, subsequent to the step of removing the resist layer, separating the metal layer into a first metal layer that is in contact with the first conducting member and a second metal layer that is in contact with the second conducting member by selectively removing the metal layer by using the first conducting member and the second conducting member as a mask.

### (Note 4)

The method of manufacturing a light emitting module according to Note 3 further comprising, subsequent to the step of separating the metal layer, forming a metal film on the exposed surfaces of each of the first conducting member, the first bonding member, and the first electrode, and on the exposed surfaces of each of the second conducting member, the second bonding member, and the second electrode.

### (Note 5)

The method of manufacturing a light emitting module according to any of Notes 1 to 4, wherein the first bonding member and the second bonding member are formed by electroplating.

### (Note 6)

The method of manufacturing a light emitting module according to any of Notes 1 to 5, wherein the step of providing an intermediate structure comprises a step of providing a wiring board, and a step of disposing the first conducting member and the second conducting member on the metal layer.

### (Note 7)

The method of manufacturing a light emitting module according to Note 6 wherein the first conducting member and the second conducting member are formed by a plating method.

### (Note 8)

The method of manufacturing a light emitting module according to any of Notes 1 to 7, wherein a shape of the outer periphery of the lower surface of the light emitting element is a quadrangle, and in the step of disposing the light emitting element, entireties of two opposing sides of four sides of the quadrangle are in contact with the resist layer.

### (Note 9)

A light emitting module comprising:

a wiring board having an upper surface, the wiring board comprising
a first metal layer disposed at the upper surface, and
a second metal layer disposed on the upper surface;

a first conducting member disposed on the first metal layer in contact with the first metal layer;

a second conducting member disposed on the second metal layer in contact with the second metal layer;

a first bonding member disposed on the first conducting member in contact with the first conducting member;

a second bonding member disposed on the second conducting member in contact with the second conducting member; and

a light emitting element having a lower surface, the light emitting element comprising a first electrode disposed at the lower surface and in contact with the first bonding member, and a second electrode disposed on the lower surface and in contact with the second bonding member, the lower surface opposing the upper surface of the wiring board, wherein,

in a plan view, a portion at an end of the first conducting member is exposed from the first bonding member, and a portion at an end of the second conducting member is exposed from the second bonding member.

### (Note 10)

The light emitting module according to Note 9, wherein, in a plan view, the portion of the first conducting member exposed from the first bonding member and the portion of the second conducting member exposed from the second bonding member are located between the first bonding member and the second bonding member.

What is claimed is:

1. A method of manufacturing a light emitting module, the method comprising:
providing an intermediate structure that comprises:
a wiring board having an upper surface and comprising a metal layer disposed at the upper surface,
a first conducting member disposed on the metal layer to be in contact with the metal layer, and
a second conducting member disposed on the metal layer to be in contact with the metal layer and apart from the first conducting member;
disposing, on the intermediate structure, a resist layer having a first opening and a second opening, such that the first conducting member is exposed in the first opening and the second conducting member is exposed in the second opening;
providing a light emitting element having a lower surface, the light emitting element comprising a first electrode and a second electrode that are spaced apart from each other at the lower surface, and disposing the light emitting element on the resist layer such that the first electrode and the second electrode respectively face the first conducting member and the second conducting member while a portion of an outer periphery of the lower surface is exposed from the resist layer in the first opening and the second opening;
forming a first bonding member on the first conducting member to be in contact with the first conducting member and the first electrode and forming a second bonding member on the second conducting member to be apart from the first bonding member and in contact with the second conducting member and the second electrode; and
removing the resist layer.

2. The method of manufacturing a light emitting module according to claim 1, wherein, in the step of disposing the light emitting element, the resist layer is pressed by the light emitting element to thereby cover portions at an end of the first conducting member and portions at an end of the second conducting member.

3. The method of manufacturing a light emitting module according to claim 1 further comprising, subsequent to the step of removing the resist layer, separating the metal layer into a first metal layer that is in contact with the first conducting member and a second metal layer that is in contact with the second conducting member by selectively removing the metal layer by using the first conducting member and the second conducting member as a mask.

4. The method of manufacturing a light emitting module according to claim 3 further comprising, subsequent to the step of separating the metal layer, forming a metal film on the exposed surfaces of each of the first conducting member, the first bonding member, and the first electrode, and on the exposed surfaces of each of the second conducting member, the second bonding member, and the second electrode.

5. The method of manufacturing a light emitting module according to claim 1, wherein the first bonding member and the second bonding member are formed by electroplating.

6. The method of manufacturing a light emitting module according to claim 1, wherein the step of providing an intermediate structure comprises a step of providing a wiring board, and a step of disposing the first conducting member and the second conducting member on the metal layer.

7. The method of manufacturing a light emitting module according to claim 6 wherein the first conducting member and the second conducting member are formed by a plating method.

8. The method of manufacturing a light emitting module according to claim 1, wherein a shape of the outer periphery of the lower surface of the light emitting element is a quadrangle, and in the step of disposing the light emitting element, entireties of two opposing sides of four sides of the quadrangle are in contact with the resist layer.

9. A light emitting module comprising:
a wiring board having an upper surface, the wiring board comprising:
a first metal layer disposed at the upper surface, and
a second metal layer disposed on the upper surface;
a first conducting member disposed on the first metal layer in contact with the first metal layer;
a second conducting member disposed on the second metal layer in contact with the second metal layer;
a first bonding member disposed on the first conducting member in contact with the first conducting member;
a second bonding member disposed on the second conducting member in contact with the second conducting member; and
a light emitting element having a lower surface, the light emitting element comprising a first electrode disposed at the lower surface and in contact with the first bonding member, and a second electrode disposed on the lower surface and in contact with the second bonding member, the lower surface opposing the upper surface of the wiring board, wherein,
in a plan view, a portion at an end of the first conducting member is exposed from the first bonding member, and a portion at an end of the second conducting member is exposed from the second bonding member.

10. The light emitting module according to claim 9, wherein, in a plan view, the portion of the first conducting member exposed from the first bonding member and the portion of the second conducting member exposed from the second bonding member are located between the first bonding member and the second bonding member.
